(19) United States
(12) Patent Application Publication
(10) Pub. No.: US 2007/0187676 A1
(43) Pub. Date: Aug. 16, 2007

(54) ORGANIC ELECTRO-LUMINESCENT DISPLAY AND METHOD OF FABRICATING THE SAME

(75) Inventors: Kyung-bae PARK, Seoul (KR); Takashi NOGUCHI, Yongin-si (KR); Jong-man KIM, Seoul (KR); Jang-yeon KWON, Seongnam-si (KR); Ji-sim JUNG, Incheon-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/675,132

(22) Filed: Feb. 15, 2007

(30) Foreign Application Priority Data
Feb. 15, 2006 (KR) 10-2006-0014695

(51) Int. Cl. H01L 29/08

(52) U.S. Cl. 257/40

(57) ABSTRACT

Provided are an organic electro-luminescent display (“OELD”) and a method of fabricating the OLED. The OELD includes an organic light emitting diode (“OLED”), a driving transistor driving the OLED, and a switching transistor controlling an operation of the driving transistor. The driving transistor includes an active layer having a crystal structure grown in a direction parallel to a current channel of the driving transistor, and the switching transistor includes an active layer having a crystal structure grown in a direction perpendicular to a current channel of the switching transistor. Accordingly, the requirements for the switching transistor and the driving transistor can be satisfied in designing the OELD. Therefore, it is possible to efficiently fabricate a low-mobility switching transistor and a high-mobility driving transistor.

This application claims priority to Korean Patent Application No. 10-2006-0014695, filed on Feb. 15, 2006 and all the benefits accruing therefrom under 35 U.S.C. §119, and the contents of which in its entirety are herein incorporated by reference.

### BACKGROUND OF THE INVENTION

1. Field of the Invention

The present invention relates to an organic electro-luminescent display (“OELD”) and a method of fabricating the OELD, and more particularly, to an OELD including a plurality of transistors having different mobilities and low off-current leakage, and a method of fabricating the OELD.

2. Description of the Related Art

Active matrix organic electro-luminescent displays (“AM-OELDs”) basically include a switching transistor and a driving transistor. As is well known in the art, the switching transistor must have low off-current leakage characteristics, while the driving transistor must have high mobility characteristics.

In general, since a switching transistor and a driving transistor are obtained from a silicon layer that is fabricated in the same conditions, it is difficult to obtain the switching and driving transistors with opposite characteristics as described above. To reduce the mobility and off-current leakage of the switching transistor, a low doped drain (“LDD”) structure or an off-set structure is formed on an active layer of the switching transistor during a process of fabricating the switching transistor and the driving transistor using high-mobility silicon.

The LDD or offset structure is formed in a separate process during an organic electro-luminescent display (“OELD”) fabrication process resulting in incurring high costs for the OELD fabrication process.

### BRIEF SUMMARY OF THE INVENTION

The present invention provides a technique for decreasing a leakage current without using the LDD or offset structure of the conventional structure.

The present invention provides a high-quality organic electro-luminescent display (“OELD”) having a switching transistor with a low leakage current and a driving transistor with high mobility, and a method of fabricating the high-quality OELD.

According to exemplary embodiments of the present invention, there is provided an OELD including an organic light emitting diode (“OLED”), a driving transistor driving the OLED, the driving transistor including an active layer having a crystal structure grown in a direction parallel to a current channel of the driving transistor, and a switching transistor controlling an operation of the driving transistor, the switching transistor including an active layer having a crystal structure grown in a direction perpendicular to a current channel of the switching transistor.

According to other exemplary embodiments of the present invention, there is provided a method of fabricating an OELD including an OLED, a driving transistor driving the OLED, and a switching transistor controlling an operation of the driving transistor, the method including forming an electrically insulative and thermally conductive layer on a substrate, forming a first silicon island for an active layer of the switching transistor on the electrically insulative and thermally conductive layer, wherein the first silicon island extends in a direction parallel to a current channel of the switching transistor, forming a second silicon island for an active layer of the driving transistor on the electrically insulative and thermally conductive layer, wherein the second silicon island extends in a direction perpendicular to a current channel of the driving transistor, crystallizing the first silicon island to form the active layer of the switching transistor that has a crystal structure grown in a direction perpendicular to the current channel of the switching transistor, crystallizing the second silicon island to form the active layer of the driving transistor that has a crystal structure grown in a direction parallel to the current channel of the driving transistor, and fabricating the switching transistor and the driving transistor using the active layers.

The electrically insulative and thermally conductive layer may be formed of a material selected from a group consisting of aluminum ceramic, cobalt ceramic, and iron ceramic. The aluminum ceramic may be one of Al₂O₃ and AlN. The cobalt ceramic may be one of CoO and CO₃N₄. The iron ceramic may be one of FeO, Fe₂O₃, Fe₃O₄, and Fe₂N.

The crystallization of the first silicon island and the second silicon island may be performed by excimer laser annealing (“ELA”). The crystallization of the first silicon island and the second silicon island may be performed with a laser energy density of 400 mJ/cm² or more. The width of the active layer of the switching transistor and the length of the active layer of the driving transistor may be 4 microns or more.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates the thermal distribution of an exemplary silicon island during a crystallization process of the exemplary silicon island, which is used in an exemplary organic electro-luminescent display (“OELD”) and a method of fabricating the OELD;

FIG. 2 illustrates a heat flow path through an exemplary silicon island and the creation and growth of a crystal nucleus;

FIG. 3 is a scanning electron microscope (“SEM”) image of an exemplary polysilicon according to the present invention;

FIG. 4 is an SEM image of a polysilicon obtained using a conventional method;

FIGS. 5A through 5F are perspective views illustrating an exemplary method of fabricating an exemplary polysilicon layer, which is used as an active layer of an exemplary transistor, according to an exemplary embodiment of the present invention;

FIG. 6A illustrates an equivalent circuit diagram of an exemplary OELD according to an exemplary embodiment of the present invention;

FIGS. 6B and 6C illustrate the crystal growth directions of active layers of exemplary switching and driving thin film transistors (“TFTs”), respectively, of the exemplary OELD illustrated in FIG. 6A;

FIG. 7A illustrates a layout diagram of a unit pixel of an exemplary OELD according to an exemplary embodiment of the present invention;

FIG. 7B illustrates a sectional view taken along line VII-VII of FIG. 7A, according to an exemplary embodiment of the present invention; and

FIGS. 8A through 8V are layout diagrams and corresponding sectional views illustrating an exemplary method of fabricating an exemplary OELD according to an exemplary embodiment of the present invention.

### DETAILED DESCRIPTION OF THE INVENTION

The present invention will now be described more fully with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

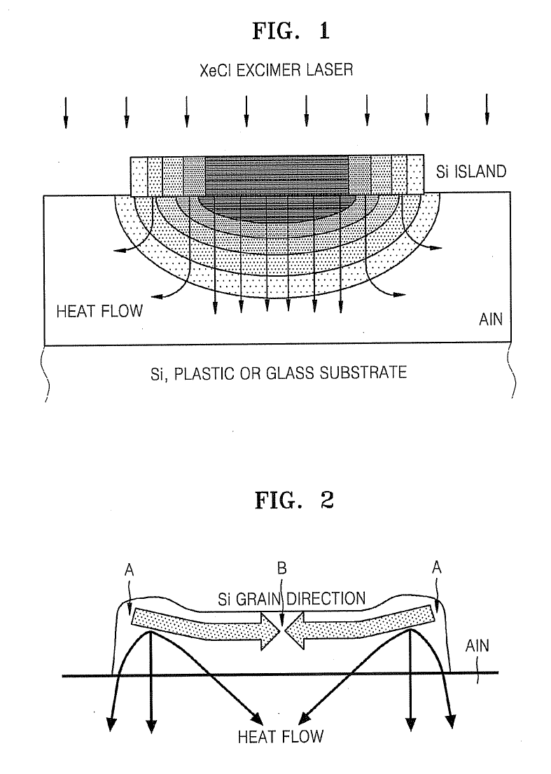

FIG. 1 illustrates the thermal distribution of an exemplary silicon island during a crystallization process of the exemplary silicon island, which is used in an exemplary organic electro-luminescent display (“OELD”) and an exemplary method of fabricating the exemplary OELD. FIG. 2 illustrates a heat flow path from an exemplary silicon island and the creation and growth of an exemplary crystal nucleus.

Referring to FIG. 1, a thermally conductive layer is formed of a high thermal conductive material, such as but not limited to aluminum nitride (AlN), on a glass or plastic substrate. The silicon island is formed on the thermally conductive layer.

A XeCl excimer laser beam with a wavelength of 308 nm is irradiated onto the silicon island such that the silicon island is sufficiently heated and completely melted. Thermal conduction from the high-temperature silicon island immediately occurs, and thus, a three-dimensional heat flow occurs in the thermally conductive layer. The thermal conduction in the thermal conductive layer occurs more rapidly and greatly in the lateral direction of the thermally conductive layer than in the other direction of the substrate. In FIG. 1, an arrow indicates the path of the heat flow from above, where the silicon island is relatively positioned above the thermally conductive layer. In FIG. 1, a dark region is higher in temperature than a lighter region. The central region of the silicon island is higher in temperature than the other regions, and the temperature decreases on both sides of the silicon island. This lateral thermal gradient causes the path of thermal conduction and the growth of the crystal nucleus, as illustrated in FIG. 2. According to the rapid thermal conduction by the thermally conductive layer, heat rapidly dissipates from both sides of the silicon island. Accordingly, a crystalline nucleus is first created on both ends A of the silicon island, the crystal growth gradually advances to the center of the silicon island, and a grain boundary B is created at a central region of the silicon island. According to the present invention, the silicon island is pre-patterned. Therefore, during an annealing process, a cooling operation rapidly begins from both ends of the silicon island, and thus, a crystalline nucleus is created on both ends A of the silicon island. That is, according to the present invention, since the creation position of the crystalline nucleus is predetermined, the silicon island can be heat-treated under full-melting conditions. The ability to fully melt allows a heat-treatment operation in a very wide process window, that is, a very wide temperature range. Meanwhile, since the position and size of the pre-patterned silicon island can be controlled based on design, a high-quality polysilicon can be formed at a desired position on the substrate.

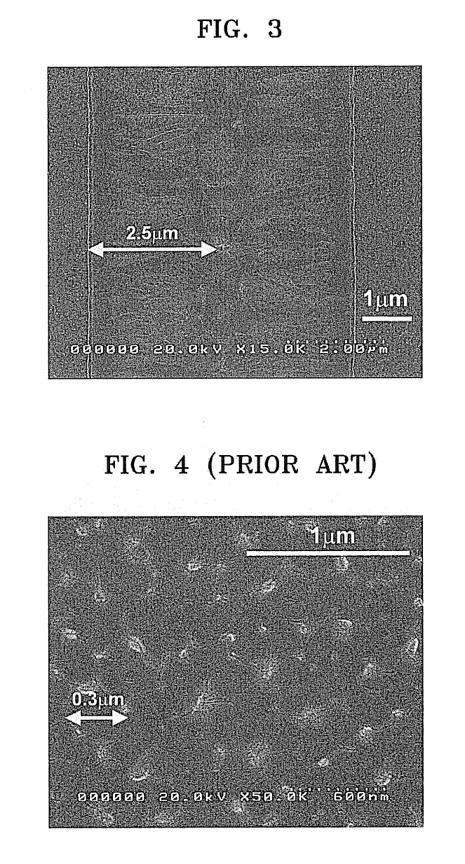

According to the present invention, a polysilicon illustrated in FIG. 3 can be obtained. FIG. 3 is a scanning electron microscope (“SEM”) image of the polysilicon obtained according to the present invention. As can be seen from FIG. 3, the width of a crystal is 2.5 μm, or about 2.5 μm, and the crystalline nucleus is created at the center, or central region, of the polysilicon. A crystal growth direction is oriented along the width (i.e., left to right direction in FIG. 3) of the polysilicon. Accordingly, the polysilicon has high mobility width wise but low mobility height wise (i.e., up and down direction in FIG. 3). In the present invention, the silicon island is formed in the shape of a rectangle extended in a direction and the silicon crystal is grown width wise rather than length wise. This method of allowing the selection of the crystal growth direction is used for the fabrication of the OELD, as will be further described below.

FIG. 4 is an SEM image of polysilicon obtained by a conventional method using excimer laser anneal (“ELA”). As can be seen from FIG. 4, the grain diameter of the conventional polysilicon is 0.3 μm, which is much smaller than that of the polysilicon illustrated in FIG. 3.

The thermally conductive layer described above has a higher thermal conductivity than the substrate and the silicon, and may be formed of AlN. The AlN not only has a high thermal conductivity of 260 W/mK or more, but also a band gap of about 6.3 eV, and thus, exhibits good electrical insulative properties. Also, the AlN not only has high physical hardness, but also high optical transparency and good chemical stability. Accordingly, the AlN is used to fabricate the thermally conductive layer of the present invention. While AlN has been described as used to fabricate the thermally conductive layer, the thermally conductive layer may alternatively be formed of a high thermal conductive material selected from the group consisting of aluminum ceramic such as Al₂O₃ and AlN, cobalt ceramic such as CoN and CaO, and iron ceramic such as FeO, Fe₂O₃, Fe₃O₄, and Fe₂N.

The silicon island with the above orientation in terms of crystal structure has high mobility in a direction parallel to a crystal direction but has low mobility in a direction perpendicular to the crystal direction. A transistor having an active layer with relatively-low mobility exhibits the characteristics of relatively-low leakage current.

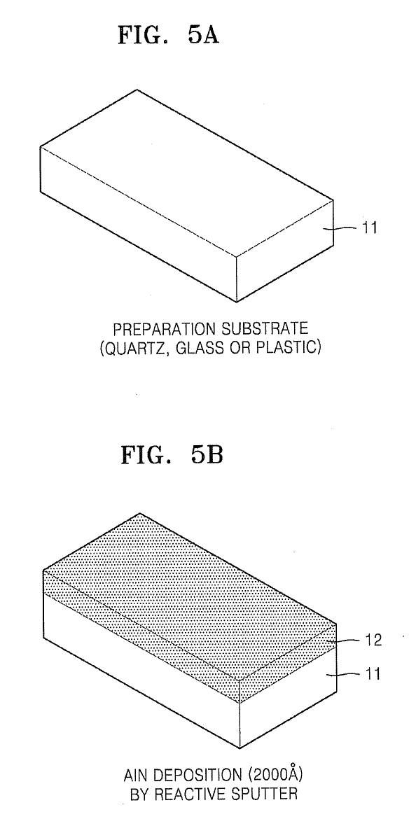

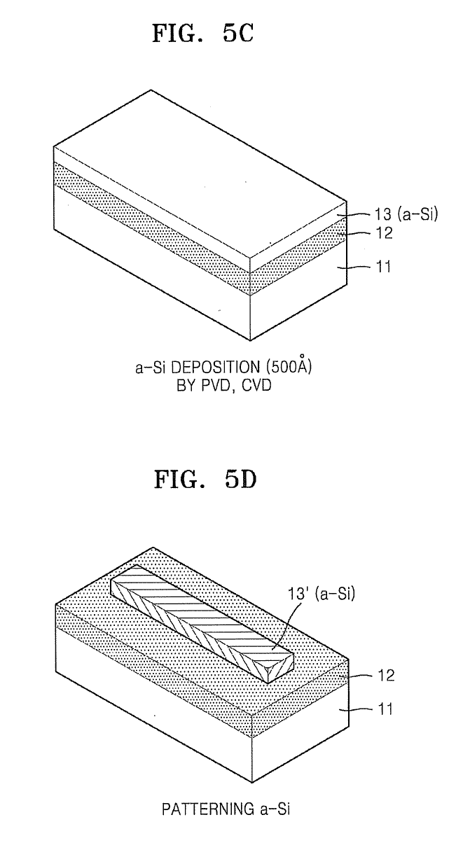

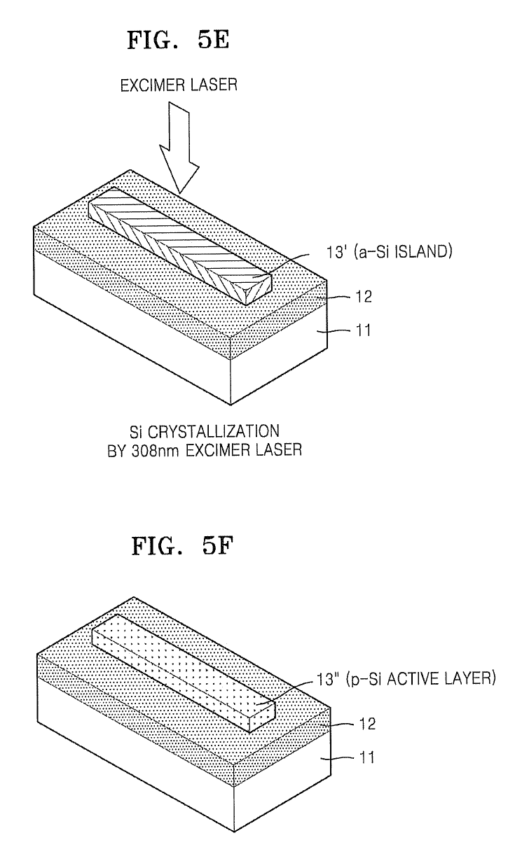

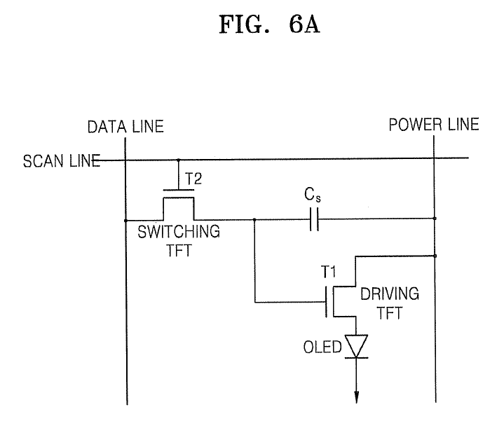

A method of fabricating active layers of switching and driving thin film transistors (“TFTs”), which have a required crystal direction, will now be described with reference to FIGS. 5A through 5F.

FIGS. 5A through 5F are perspective views illustrating an exemplary method of fabricating active layers of exemplary switching and driving TFTs according to an exemplary embodiment of the present invention. As illustrated in FIG. 5A, a substrate 11 formed of quartz, glass, or plastics is prepared.

As illustrated in FIG. 5B, a thermally conductive layer 12 is deposited on the substrate 11 to a thickness of about 2000 Å. The thermally conductive layer 12 is formed of a high thermally conductive material. In the deposition process, Al and 10-sccm N (that is, 10 standard cubic centimeters per minute N, where standard is referenced to 0 degrees Celsius and 760 Torr) are respectively used as a target material and reactive gas, an internal pressure of a reaction chamber is about 10 mTorr, and plasma power is about 300 W.

As illustrated in FIG. 5C, an amorphous silicon (“a-Si”) layer 13 is formed on the thermally conductive layer 12 to a thickness of about 500 Å by a deposition process such as chemical vapor deposition (“CVD”) or physical vapor deposition (“PVD”). The a-Si layer 13 is preferably formed by PVD. In the PVD process, Si and 50-sccm Ar are respectively used as a sputtering target material and reactive gas, and the air pressure is set to about 5 mTorr.

As illustrated in FIG. 5D, a dry etching process is performed to pattern the a-Si layer 13, thereby forming a silicon island 13′. In an exemplary embodiment, the silicon island 13′ is formed such that it has a width of 4 microns and a length of 4 microns or more. This a-Si island 13′ is used as an active layer of a semiconductor device such as a TFT.

As illustrated in FIG. 5E, an excimer laser is used to anneal the silicon island 13′. In the exemplary annealing process, a 308-nm XeCl excimer laser is used and the laser energy density is set to 400 mJ/cm2 or more. By this annealing process, a TFT active layer 13″ with a large-grain crystal structure is formed at a desired position on the substrate 11 as illustrated in FIG. 5F. The TFT active layer 13″ has a crystal growth direction in parallel to the width of the TFT active layer 13″, such as the crystal growth direction illustrated in FIG. 3.

The active layer 13″ obtained through the above process is used to fabricate a TFT. At this point, in order to fabricate an OELD having a switching TFT and a driving TFT, it is necessary to fabricate two silicon islands in each unit pixel.

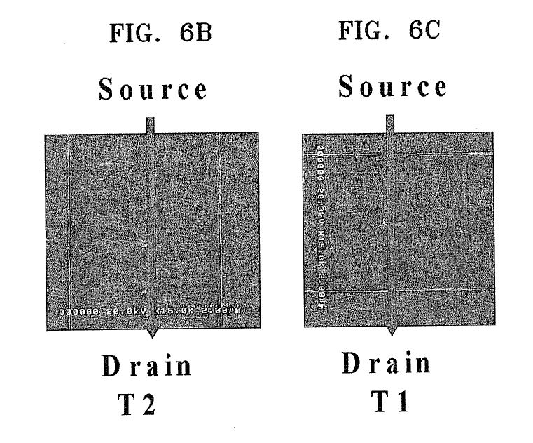

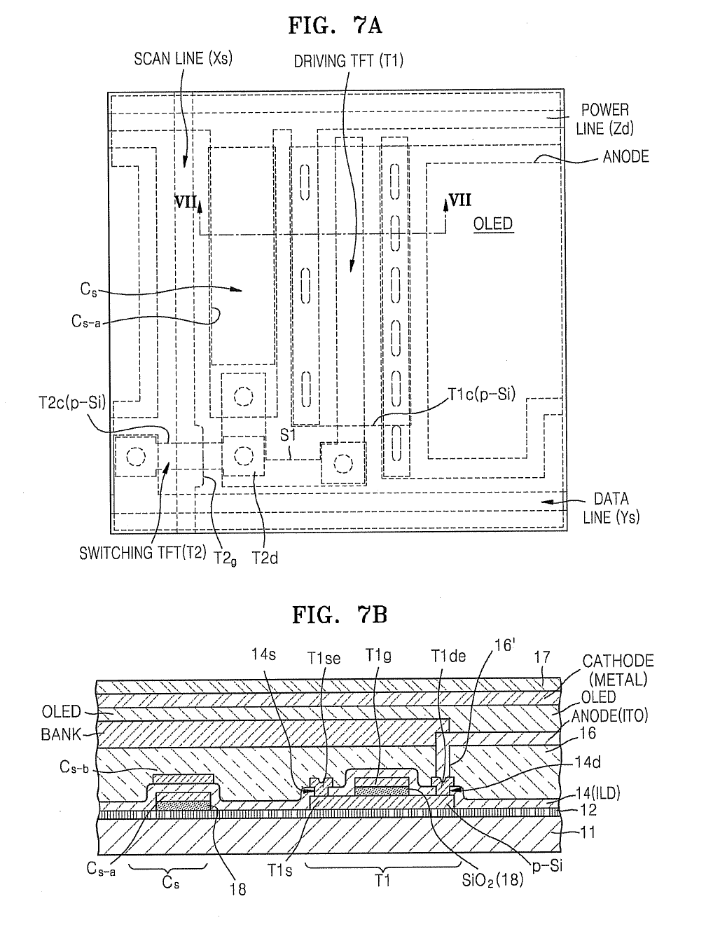

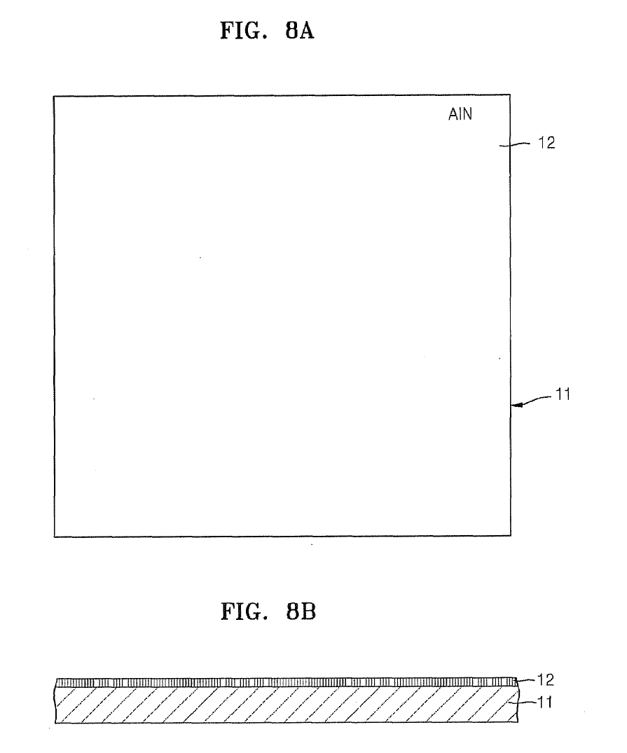

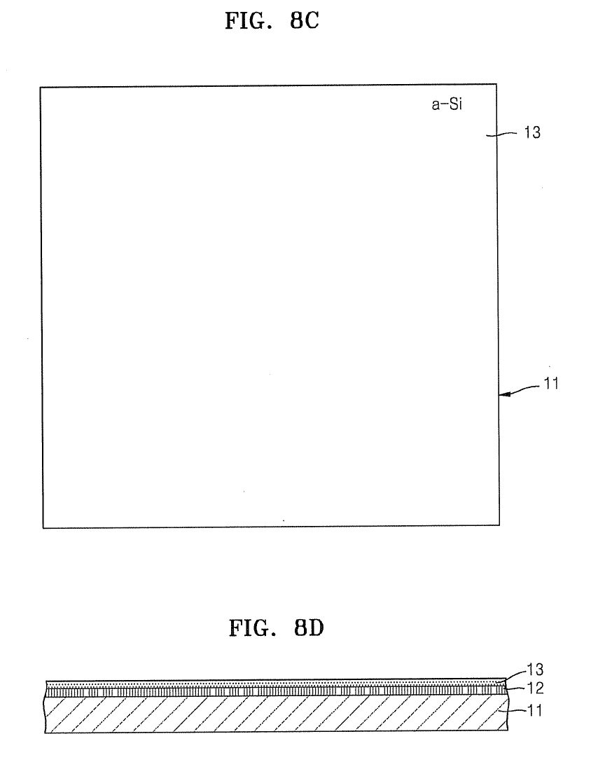

FIG. 6A illustrates an equivalent circuit diagram of a unit pixel (or a sub-pixel) of an exemplary 2 transistor-1 capacitor OELD according to an exemplary embodiment of the present invention.

Referring to FIG. 6A, a driving voltage Vdd (not shown) is applied to a source of a driving transistor T1 via a power line, and an anode of an organic light emitting diode (“OLED”) is connected to a drain of the driving transistor T1. A storage capacitor Cₛ is connected in parallel to the source and gate of the driving transistor T1, and a cathode of the OLED is grounded. A drain of a switching transistor T2 is connected to the gate of the driving transistor T1, and a source of the switching transistor T2 is connected to a data line. A gate of the switching transistor T2 is connected to a scan line, also known as a gate line.

FIGS. 6B and 6C illustrate the relationship between current channel directions (denoted by the arrows) of the exemplary driving and switching TFTs T1 and T2 with respect to silicon crystal directions. In both the driving and switching TFTs T1 and T2, the current channel direction is the direction from the source to the drain. As illustrated in FIG. 6C, a current channel of the driving TFT T1 is disposed parallel to a crystal growth direction of an active layer, while a current channel of the switching TFT T2, as illustrated in FIG. 6B, is disposed perpendicular to a crystal growth direction of an active layer.

An exemplary OELD and an exemplary method of fabricating the exemplary OELD according to an exemplary embodiment of the present invention will now be described.

FIG. 7A is a layout diagram of a unit pixel (or a sub-pixel) of an exemplary OELD according to an exemplary embodiment of the present invention.

Referring to FIG. 7A, a data line Ys and a power line Zd applying a driving voltage Vdd are disposed in parallel to each other. A scan line Xs, also known as a gate line, is disposed perpendicular to the data line Ys and the power line Zd. A switching TFT T2 is disposed at an intersection of the scan line Xs and the data line Ys, and a driving TFT T1 is disposed near an intersection of the scan lines Xs and the power line Zd. A storage capacitor Cₛ is disposed between the switching TFT T2 and the driving TFT T1. An electrode C_{s-b} (shown in FIG. 7B) of the storage capacitor Cₛ extends from the power line Zd, and the other electrode Cₛ₋ₐ of the storage capacitor Cₛ is connected through a line layer S1 to a drain T2d of the switching TFT T2 and a gate T1g (shown in FIG. 7B) of the driving TFT T1. A gate T2g of the switching TFT T2 extends from the scan line Xs. In the illustrated embodiment, for both the driving TFT T1 and the switching TFT T2, the source is located to the left of the drain, and thus the current channel direction of the driving TFT T1 and the switching TFT T2 is in the direction from left to right, however it should be understood that the orientations are relative and may be interpreted accordingly with respect to the other elements of the exemplary OLED.

According to a feature of the present invention, an active layer T1c formed of p-Si of the driving TFT T1 extends in a direction perpendicular to a current channel (or a current flow direction) of the driving TFT T1, and a silicon crystal of the active layer T1c is grown in a direction parallel to the current channel thereof. On the other hand, an active layer T2c of the switching TFT T2 extends in a direction parallel to the current channel of the switching TFT T2, and a silicon crystal of the active layer T2c is grown in a direction perpendicular to the current channel thereof. For example, as in the illustrated embodiment, the active layer T2c may extend in a left to right direction. The active layer T2c, which extends in the left to right direction, extends parallel to the left to right direction of the current channel of the switching TFT T2. Also, the longitudinal dimension of the active layer T2c in the left to right direction is greater than a dimension of the active layer T2c in the up and down direction. Thus, the active layer T2c may be grown in the up and down direction (or down and up direction) perpendicular to the current channel of the switching TFT T2 since the silicon crystal is grown width wise rather than length wise.

FIG. 7B illustrates a sectional view taken along line VII-VII as illustrated in FIG. 7A, which illustrates the cross-sections of the exemplary storage capacitor Cₛ and the exemplary driving TFT T1, according to an exemplary embodiment of the present invention.

Referring to FIG. 7B, an electrically insulative and thermally conductive layer 12 is formed on a substrate 11, and the storage capacitor Cₛ and the driving TFT T1 are formed on the electrically insulative and thermally conductive layer 12. The electrically insulative and thermally conductive layer 12 is a buffer layer formed of an insulating material such as AlN, which facilitates the crystallization of silicon during a heat treatment process for the silicon island. The driving TFT T1 includes a polysilicon layer p-Si formed on the electrically insulative and thermally conductive layer 12, a gate insulating layer 18 formed on the polysilicon layer p-Si, and a gate T1g formed on the gate insulating layer 18. The polysilicon layer p-Si includes a source T1s and a drain T1d (opposite the source T1s), and the gate insulating layer 18 is formed of, for example, SiO₂. An interlayer dielectric (“ILD”) layer 14 is formed on the driving TFT T1. The ILD layer 14 includes a plurality of insulating layers that are formed of, for example, SiO₂ and SiNₓ. Via holes 14s and 14d, also known as contact holes, are formed in the ILD layer 14 such that the via holes 14s and 14d form communication channels with the source T1s and the drain T1d of the p-Si layer, respectively. A metallic source electrode T1se and a metallic drain electrode T1de are formed on the ILD layer 14 such that they fill the via holes 14s and 14d, respectively.

The storage capacitor Cₛ includes a lower electrode Cₛ₋ₐ, an upper electrode C_{s-b}, and the ILD layer 14 between the lower and upper electrodes Cₛ₋ₐ and C_{s-b}. The lower electrode Cₛ₋ₐ and the gate T1g are simultaneously formed of the same material. An insulating layer 16 is formed on the storage capacitor Cₛ and the driving TFT T1, and a via hole 16′ corresponding with the drain electrode T1de of the driving TFT T1 is formed in the insulating layer 16. An anode is formed on the insulating layer 16 such that it fills the via hole 16′. The anode is formed of a transparent conductive material such as, but not limited to, indium tin oxide (“ITO”). A bank is formed of an insulating material on one side of the anode. An OLED is formed on the anode and the bank. The OLED includes a hole transport layer, a luminescent layer, and an electron transport layer. A metallic cathode is formed on the OLED, and a passivation layer 17 is formed on the metallic cathode. Although not shown in FIG. 7B, the switching TFT T2 is formed simultaneously with the driving TFT T1 such that it also includes a polysilicon layer, a gate insulating layer, a gate, an ILD layer, a source electrode, and a drain electrode that are formed of the same materials as the corresponding elements of the driving TFT T1.

The above and equivalent layout of the OELD is merely exemplary and is not intended to limit the scope of the present invention.

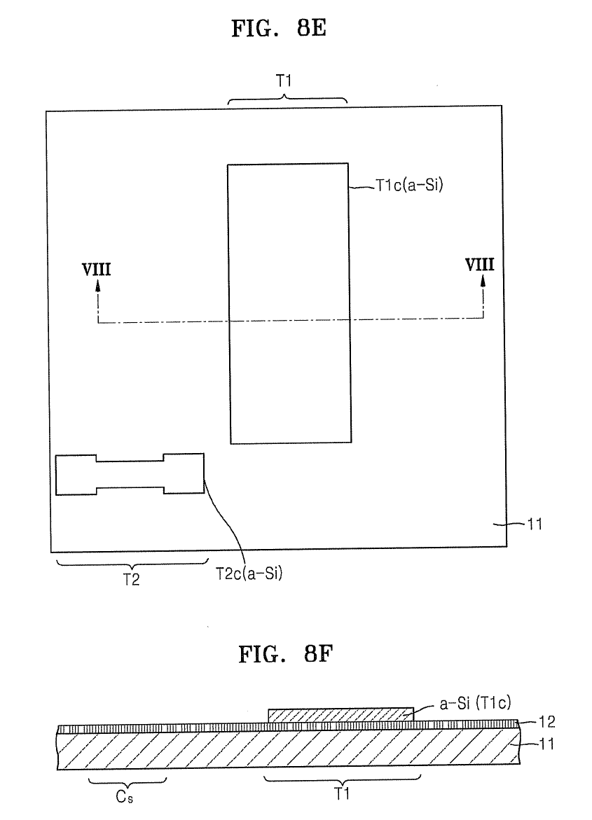

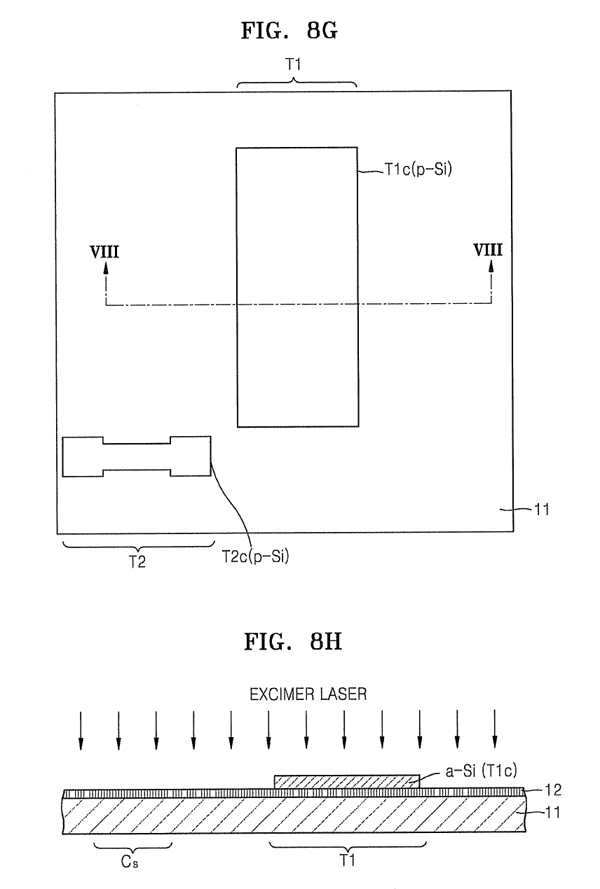

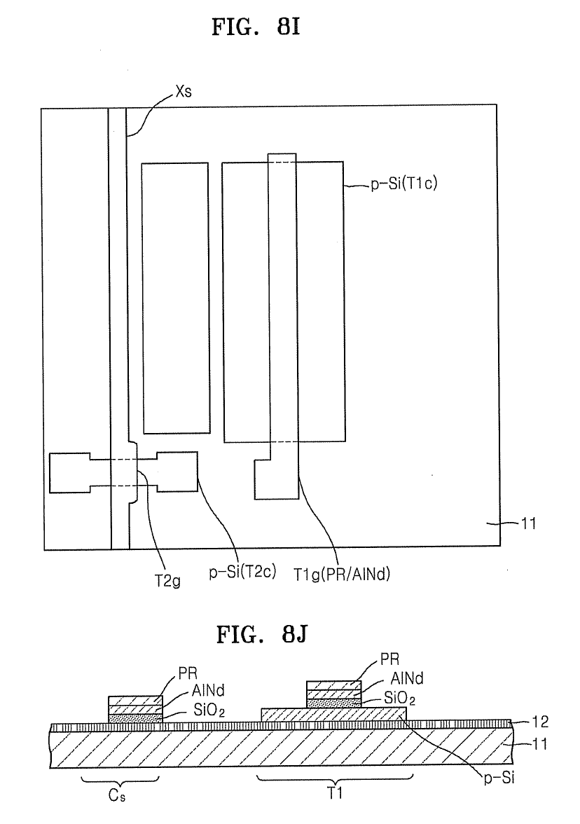

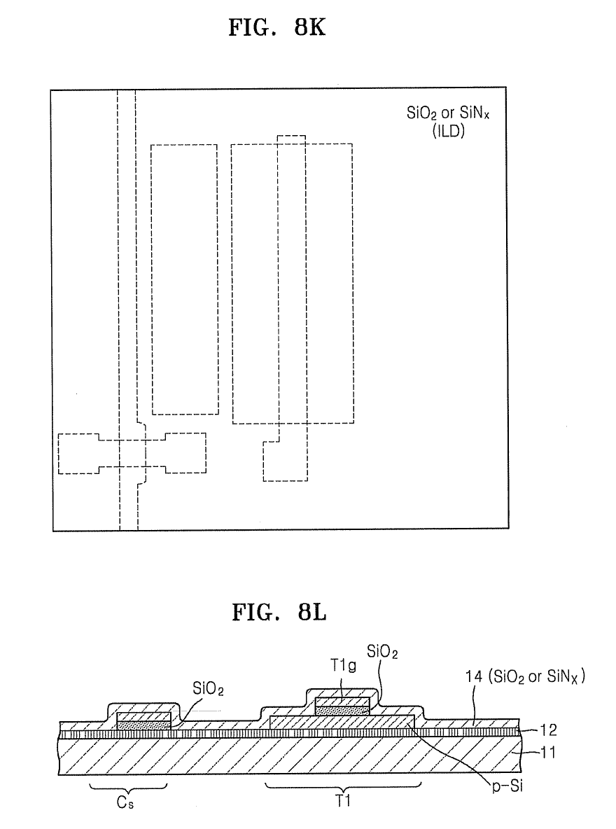

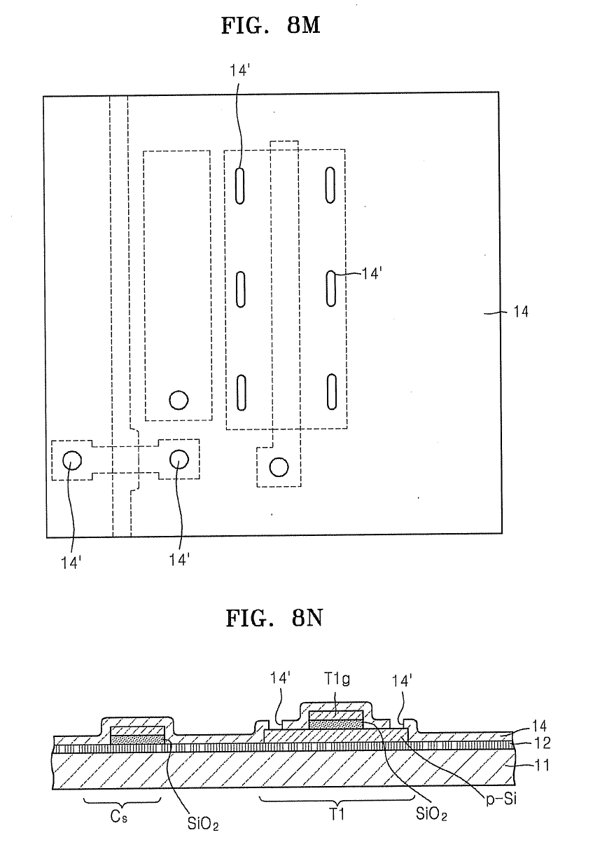

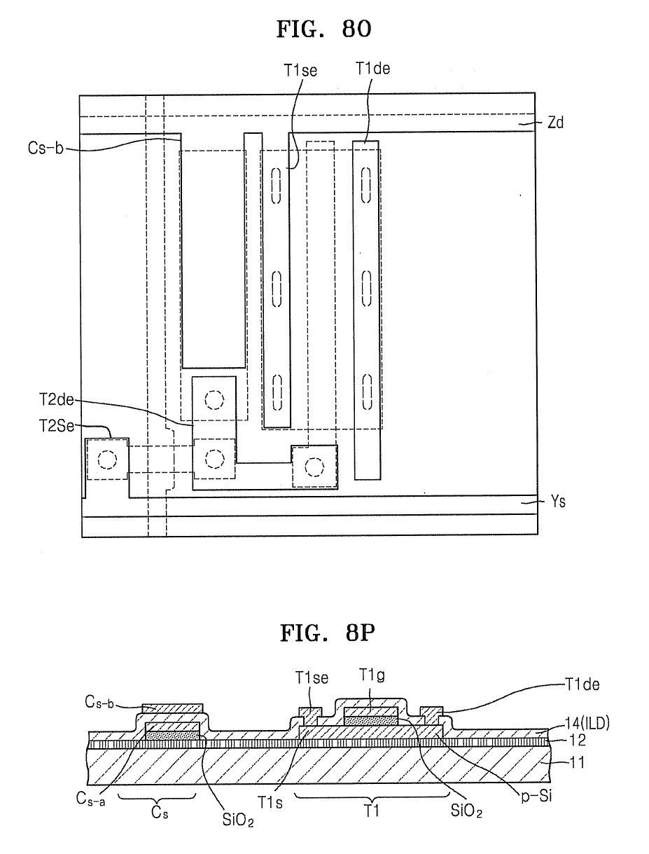

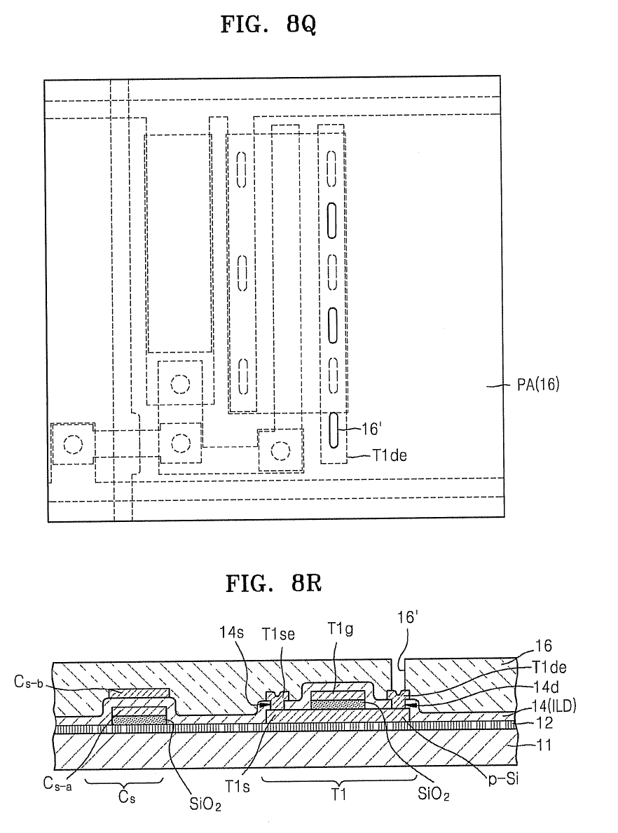

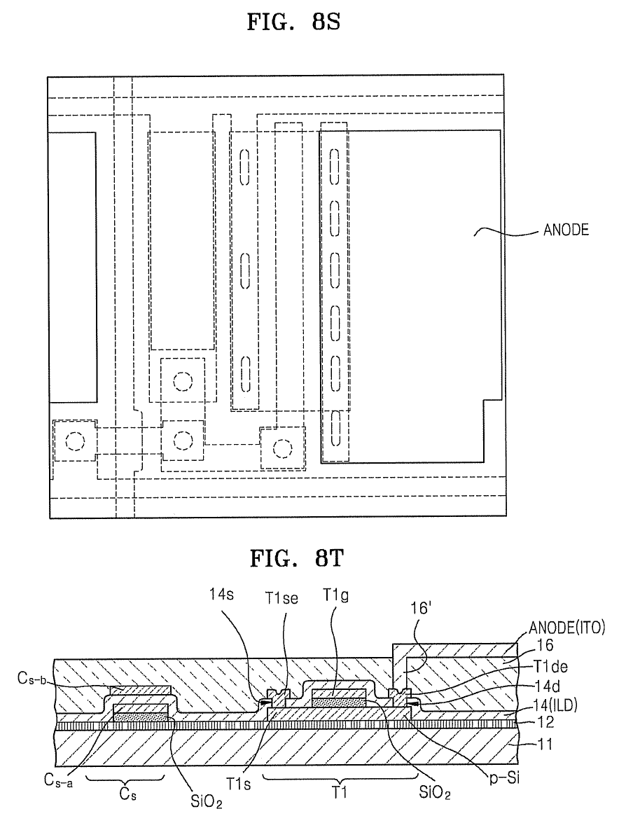

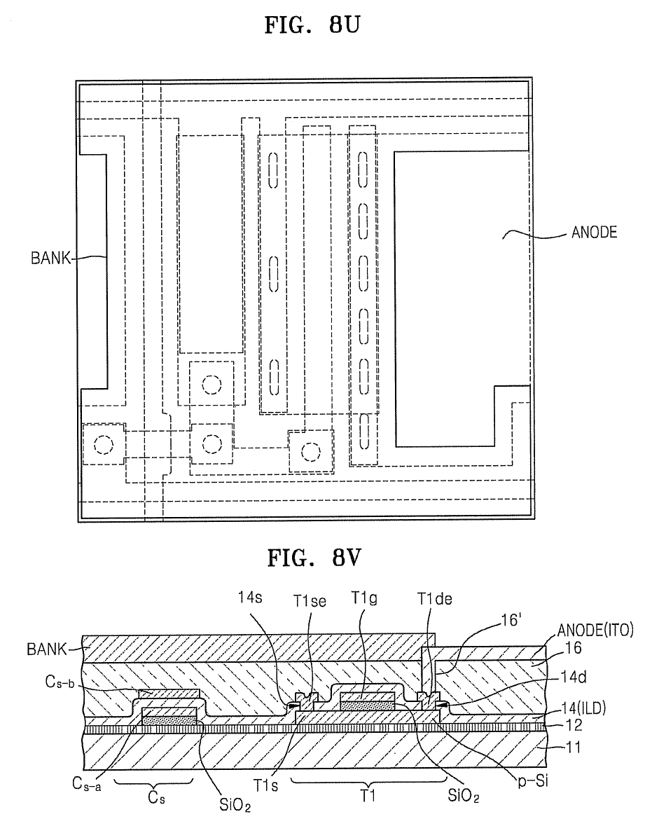

FIGS. 8A through 8V are layout diagrams and corresponding sectional views illustrating an exemplary method of fabricating an exemplary OELD according to an exemplary embodiment of the present invention. In each pair of FIGS. 8A through 8U, a first figure in each pair is a layout diagram of an exemplary unit pixel, while a second figure in each pair is a sectional view taken along line VIII-VIII illustrated in FIG. 8E or 8G to illustrate an exemplary storage capacitor and an exemplary driving TFT.

As illustrated in FIGS. 8A and 8B, a thermally conductive layer 12 serving as a buffer layer is deposited on a substrate 11, made of glass, plastic, quartz, etc. The thermally conductive layer 12 has electrical insulating properties and high thermal conductivity. The thermally conductive layer 12 is formed of a high thermal conductive material selected from the group consisting of aluminum ceramic such as Al₂O₃ and AlN, cobalt ceramic such as CoN and CaO, and iron ceramic such as FeO, Fe₂O₃, Fe₃O₄, and Fe₂N. The thermally conductive layer 12 is preferably formed of AlN. The thermally conductive layer 12 is deposited to a thickness of about 2000 Å using a reactive sputter. In the deposition process, Al and 10-sccm N are respectively used as a target material and reactive gas, an internal pressure of a reaction chamber is about 10 mTorr, and plasma power is about 300 W.

As illustrated in FIGS. 8C and 8D, an amorphous silicon (“a-Si”) layer 13 is formed on the thermally conductive layer 12 to a thickness of about 500 Å by a deposition process such as CVD process, PVD process, and sputtering process. The a-Si layer 13 is preferably formed by PVD. In the PVD process, Si and 50-sccm Ar are respectively used as a sputtering target material and reactive gas, and the air pressure is set to about 5 mTorr.

As illustrated in FIGS. 8E and 8F, a wet or dry etching process is performed to pattern the a-Si layer 13, thereby forming a first silicon island for an active layer T1c of a driving TFT T1 and a second silicon island for an active layer T2c of a switching TFT T2. According to exemplary embodiments of the present invention, the active layer T2c of the switching TFT T2 is formed such that the active layer T2c of the switching TFT T2 extends in a direction parallel to a current channel of the switching TFT T2. On the other hand, the active layer T1c of the driving TFT T1 is formed such that the active layer T1c of the driving TFT T1 extends in a direction perpendicular to the current channel of the driving TFT T1.

As illustrated in FIGS. 8G and 8H, an ELA process is performed to anneal the first and second silicon islands, thereby transforming the a-Si into a polysilicon. In the exemplary ELA process, the 308-nm XeCl excimer laser is used and the laser energy density is set to 400 mJ/cm² or more. The ELA heat treatment process crystallizes the silicon islands as described with reference to FIGS. 1 and 2. According to the crystallization process, the active layer T2c of the switching TFT T2 is crystallized in a direction perpendicular to a current channel, and thus, has a low mobility that is lower than a mobility occurring in the crystal growth direction of the polysilicon (“p-Si”). On the other hand, a current channel of the driving TFT T1 is disposed in the crystal growth direction of the polysilicon and thus the active layer T1c of the driving TFT T1 has a high mobility.

As illustrated in FIGS. 81 to 8J, a gate insulating layer of SiO₂ and a gate material layer of, for example, an AlNd alloy are sequentially deposited on the resulting structure that is on the substrate 11. Thereafter, a photoresist mask PR is used to pattern the gate insulating layer and the gate material layer, thereby forming a gate T2g of the switching TFT T2, a gate T1g of the driving TFT T1, and a lower electrode Cₛ₋ₐ of the storage capacitor Cₛ. At this point, the gate T2g of the switching TFT T2 is formed simultaneously with the scan line Xs as a portion of the scan line Xs. After the above-described gate patterning process, an exposed region of the silicon islands, which is not covered by the gates T1g and T2g, may be doped, and the doped region is activated by a heat treatment.

As illustrated in FIGS. 8K and 8L, SiO₂ or SiNₓ is deposited on the entire upper surface of the resulting structure that is on the substrate 11, thereby forming an ILD layer 14. The ILD layer 14 may include a plurality of insulating layers.

As illustrated in FIGS. 8M and 8N, contact holes (or via holes) 14′ are formed in the ILD layer 14 by dry etching for an electrical connection between the source and drain of the silicon island, the driving and switching TFTs T1 and T2, and the storage capacitor Cₛ.

As illustrated in FIGS. 80 and 8P, an upper electrode C_{s-b} of the storage capacitor Cₛ, source and drain electrodes T2se and T2de of the switching TFT T2, and source and drain electrodes T1 se and T1 de of the driving TFT T1 are formed in the resulting structure. This process includes forming, for example, an AlNd metal layer and patterning the AlNd metal layer.

As illustrated in FIGS. 8Q and 8R, an insulating layer 16 is formed on the resulting structure that is on the substrate 11, and a via hole 16′ forming a channel corresponding with the drain electrode T1de of the driving TFT T1 is formed in the insulating layer 16.

As illustrated in FIGS. 8S and 8T, an anode material is deposited on the insulating layer 16 and fills the via hole 16′. The anode is formed of a transparent conductive material such as, but not limited to, ITO.

As illustrated in FIGS. 8U and 8V, a bank is formed on a portion of the insulating layer 16 that is not covered with the anode. The bank is formed of an insulating material such as, but not limited to, protactinium (Pa). Thereafter, general processes are performed to complete the OELD as illustrated in FIGS. 7A and 7B.

The OELD of the present invention described above uses a top gate TFT, but the present invention is not limited thereto. That is, the OELD may use a bottom gate TFT in which a gate is disposed under an active layer. The structure and method of fabricating the OELD using the bottom gate TFT will be apparent to those skilled in the art. The OELD and the method of fabricating the OELD, described above, are merely exemplary and are not intended to limit the scope of the present invention.

According to the present invention, the requirements for the switching transistor and the driving transistor can be satisfied in the design of the exemplary OELD. That is, the crystal growth direction is controlled and designed in accordance with a direction required in the active layer of each TFT. Accordingly, it is possible to efficiently fabricate the switching transistor having a low-mobility active layer and a low leakage current and the driving transistor having a high-mobility active layer and a high response speed.

The present invention can be conveniently applied to a polysilicon TFT OELD and a method of fabricating the polysilicon TFT OELD.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic electro-luminescent display comprising:
an organic light emitting diode;
a driving transistor driving the organic light emitting diode, the driving transistor including an active layer having a crystal structure grown in a direction parallel to a current channel of the driving transistor; and
a switching transistor controlling an operation of the driving transistor, the switching transistor including an active layer having a crystal structure grown in a direction perpendicular to a current channel of the switching transistor.

2. The organic electro-luminescent display of claim 1, further comprising an electrically insulative and thermally conductive layer disposed under the active layers, the electrically insulative and thermally conductive layer formed of a material selected from a group consisting of aluminum ceramic, cobalt ceramic, and iron ceramic.

3. The organic electro-luminescent display of claim 2, wherein the electrically insulative and thermally conductive layer is aluminum ceramic and is one of Al₂O₃ and AlN.

4. The organic electro-luminescent display of claim 2, wherein the electrically insulative and thermally conductive layer is cobalt ceramic and is one of CoO and CO₃N₄.

5. The organic electro-luminescent display of claim 2, wherein the electrically insulative and thermally conductive layer is iron ceramic and is one of FeO, Fe₂O₃, Fe₃O₄, and Fe₂N.

6. The organic electro-luminescent display of claim 1, wherein the width of the active layer of the switching transistor and the length of the active layer of the driving transistor are 4 microns or more.

7. The organic electro-luminescent display of claim 1, wherein the driving transistor has a higher mobility than the switching transistor.

8. A method of fabricating an organic electro-luminescent display including an organic light emitting diode, a driving transistor driving the organic light emitting diode, and a switching transistor controlling an operation of the driving transistor, the method comprising:
forming an electrically insulative and thermally conductive layer on a substrate;
forming a first silicon island for an active layer of the switching transistor on the electrically insulative and thermally conductive layer, wherein the first silicon island extends in a direction parallel to a current channel of the switching transistor;
forming a second silicon island for an active layer of the driving transistor on the electrically insulative and thermally conductive layer, wherein the second silicon island extends in a direction perpendicular to a current channel of the driving transistor;
crystallizing the first silicon island to form the active layer of the switching transistor that has a crystal structure grown in a direction perpendicular to the current channel of the switching transistor;
crystallizing the second silicon island to form the active layer of the driving transistor that has a crystal structure grown in a direction parallel to the current channel of the driving transistor; and
fabricating the switching transistor and the driving transistor using the active layers.

9. The method of claim 8, wherein the electrically insulative and thermally conductive layer, the electrically insulative and thermally conductive layer formed of a material selected from a group consisting of aluminum ceramic, cobalt ceramic, and iron ceramic.

10. The method of claim 9, wherein the electrically insulative and thermally conductive layer is aluminum ceramic and is one of Al₂O₃ and AlN.

11. The method of claim 9, wherein the electrically insulative and thermally conductive layer is cobalt ceramic and is one of CoO and CO₃N₄.

12. The method of claim 9, wherein the electrically insulative and thermally conductive layer is iron ceramic and is one of FeO, Fe₂O₃, Fe₃O₄, and Fe₂N.

13. The method of claim 8, wherein crystallizing the first silicon island and the second silicon island is performed by excimer laser annealing.

14. The method of claim 13, wherein crystallizing the first silicon island and the second silicon island is performed with a laser energy density of 400 mJ/cm² or more.

15. The method of claim 13, wherein the width of the active layer of the switching transistor and the length of the active layer of the driving transistor are 4 microns or more.

16. The method of claim 8, wherein the width of the active layer of the switching transistor and the length of the active layer of the driving transistor are 4 microns or more.
